(19) United States
(12) Patent Application Publication
(10) Pub. No.: US 2025/0387838 A1
(43) Pub. Date: Dec. 25, 2025

(54) CEMENTED CARBIDE AND COATED TOOL AND CUTTING TOOL EACH USING THE SAME

(71) Applicant: KYOCERA CORPORATION, Kyoto-shi, Kyoto (JP)

(72) Inventors: Takumi HASHIMOTO, Satsumasendai-shi, Kagoshima (JP); Hirotoshi ITO, Satsumasendai-shi, Kagoshima (JP); Naohisa MATSUDA, Satsumasendai-shi, Kagoshima (JP)

(21) Appl. No.: 18/840,495

(22) PCT Filed: Feb. 1, 2023
(86) PCT No.: PCT/JP2023/003136

§ 371 Date: Apr. 1, 2025

(30) Foreign Application Priority Data
Mar. 3, 2022 (JP) 2022-032394

(51) Int. Cl. B23B 27/14; C22C 29/08

(52) U.S. Cl. CPC B23B 27/148; C22C 29/08; B23B 2224/04; B23B 2224/32; B23B 2224/36; B23B 2228/10; B23B 2228/36

(57) ABSTRACT

A cemented carbide in a non-limiting embodiment of the present disclosure includes a hard phase including W and C, a binding phase including one or more kinds of iron group metals, and a condensed phase including Zr and Nb in which Nb/(Zr+Nb) in terms of atomic ratio is less than 0.38. A coated tool in a non-limiting embodiment of the present disclosure includes the cemented carbide and a coating layer located on a surface of the cemented carbide. A cutting tool in a non-limiting embodiment of the present disclosure includes a holder that extends from a first end toward a second end and includes a pocket on a side of the first end, and the coated tool located in the pocket.

### CROSS-REFERENCE TO RELATED APPLICATION

The present application claims priority to Japanese Patent Application No. 2022-032394, filed Mar. 3, 2022. The contents of this application are incorporated herein by reference in their entirety.

### TECHNICAL FIELD

The present disclosure relates to a cemented carbide, and a coated tool and a cutting tool each using the cemented carbide.

### BACKGROUND

Cemented carbide including WC (tungsten carbide) as a hard phase is used for a base, etc. in a coated tool, and is applied to a cutting tool, such as an end mill. For example, Japanese Patent 5424935 (Patent Document 1) describes that peeling off of a coating layer due to a difference in thermal expansion between the base and the coating layer can be avoided by ZrO₂ phases (zirconia phases) scattered in a surface of the base composed of the cemented carbide.

### SUMMARY

A cemented carbide in a non-limiting embodiment of the present disclosure includes a hard phase including W and C, a binding phase including one or more kinds of iron group metals, and a condensed phase including Zr and Nb in which Nb/(Zr+Nb) in terms of atomic ratio is less than 0.38.

A coated tool in a non-limiting embodiment of the present disclosure includes the cemented carbide and a coating layer located on a surface of the cemented carbide.

A cutting tool in a non-limiting embodiment of the present disclosure includes a holder that extends from a first end toward a second end and includes a pocket on a side of the first end, and the coated tool located in the pocket.

### BRIEF DESCRIPTION OF THE DRAWINGS

FIG. 1 is a schematic diagram illustrating a cross section of a cemented carbide in a non-limiting embodiment of the present disclosure;

FIG. 2 is a perspective view illustrating a coated tool in a non-limiting embodiment of the present disclosure;

FIG. 3 is a sectional view illustrating a neighborhood of a surface of a coated tool in a non-limiting embodiment of the present disclosure;

FIG. 4 is a sectional view illustrating a neighborhood of a surface of a coated tool in a non-limiting embodiment of the present disclosure; and

FIG. 5 is a perspective view illustrating a cutting tool in a non-limiting embodiment of the present disclosure.

### EMBODIMENT

### Cemented Carbide

A cemented carbide 1 in a non-limiting embodiment of the present disclosure is described in detail below with reference to the drawings. For the convenience of description, the drawings referred to below illustrate, in simplified form, only main members necessary for describing embodiments. Hence, the cemented carbide 1 may include any arbitrary structural member not illustrated in the drawings referred to. Dimensions of the members in the drawings faithfully represent neither dimensions of actual structural members nor dimensional ratios of these members. These points are also true for a coated tool and a cutting tool described later.

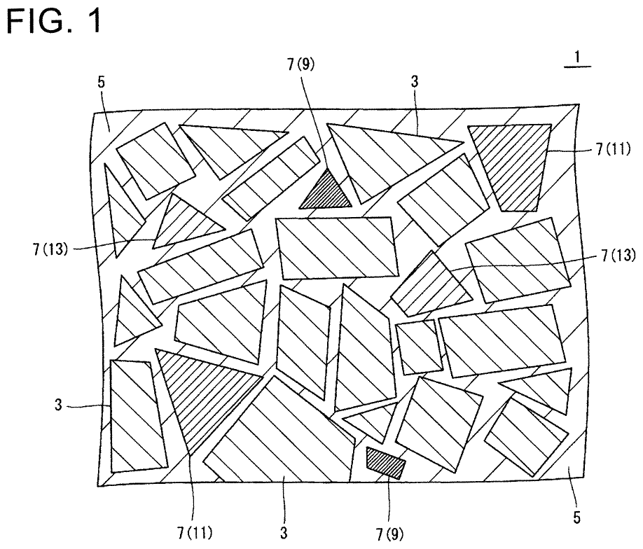

The cemented carbide 1 may include a hard phase 3, a binding phase 5, and a condensed phase 7 as in a non-limiting embodiment illustrated in FIG. 1.

The hard phase 3 may include W (tungsten) and C (carbon). In other words, the hard phase 3 may include WC. The hard phase 3 may include WC as a main component. The term “main component” as used herein may mean a component having the largest value of mass % compared to other components.

The binding phase 5 may be composed of one or more kinds of iron group metals, such as Co (cobalt) and Ni (nickel). The binding phase 5 may be composed of at least one of Co and Ni. The binding phase 5 is servable as a phase that bonds the hard phases 3 adjacent to each other. The binding phase 5 may be composed only of an iron group metal, and may include a little additive and/or impurity. Specifically, the binding phase 5 may include 95 mass % or more of the iron group metal, and may include 5 mass % or less of the additive and/or the impurity.

The condensed phase 7 may also be referred to as a so-called β phase. The condensed phase 7 is servable as a phase that imparts heat resistance to the cemented carbide 1.

Here, the condensed phase 7 may include Zr (zirconium) and Nb (niobium). That is, the condensed phase 7 may be a phase in which at least Zr and Nb are condensed. Further, Nb/(Zr+Nb) in terms of atomic ratio may be less than 0.38 in the condensed phase 7. If there are more Zr than Nb at this ratio in the condensed phase 7, it is easy to improve the heat resistance of the cemented carbide 1. Consequently, the cemented carbide 1 has high heat resistance.

A lower limit value of Nb/(Zr+Nb) in terms of atomic ratio may be larger than 0. Specifically, the lower limit value may be 0.02. Nb is an intentionally added component for the purpose of improving the heat resistance. The value of Nb/(Zr+Nb) in terms of atomic ratio may be an average value.

The condensed phase 7 may include Zr at a rate of 1-10 atom % (at %). The condensed phase 7 may also include Nb at a rate of 0.5-3 atom %.

The condensed phase 7 may further include C, Ti (titanium), Co, Ta (tantalum), and W in addition to Zr and Nb. A content rate of C in terms of atomic ratio may be highest in the condensed phase 7.

An elemental analysis for calculating atomic ratio, etc. may be carried out by, for example, Energy-dispersive X-ray Spectroscopy (EDS). The elemental analysis may be made by a cross-sectional observation using the EDS included in an electron microscope. Examples of the electron microscope may include Scanning Electron Microscope (SEM) and Transmission Electron Microscope (TEM).

The condensed phase 7 may include a first condensed phase 9. Nb/(Zr+Nb) in terms of atomic ratio may be 0.25 or less in the first condensed phase 9. In this case, it is easy to improve the heat resistance of the cemented carbide 1.

The Nb/(Zr+Nb) in terms of atomic ratio may be 0.2 or less in the first condensed phase 9. In this case, improvement of heat resistance can be expected. If made in the form of a coated tool, it is easy to improve wear resistance. The Nb/(Zr+Nb) in terms of atomic ratio may be 0.05 or more in the first condensed phase 9.

The condensed phase 7 may further include a second condensed phase 11 and a third condensed phase 13. Nb/(Zr+Nb) in terms of atomic ratio may be larger than 0.3 and may be 0.34 or less in the second condensed phase 11. Nb/(Zr+Nb) in terms of atomic ratio may be larger than 0.34 and may be less than 0.38 in the third condensed phase 13. In these cases, it is easy to improve the heat resistance of the cemented carbide 1.

A mean particle diameter of the first condensed phase 9 may be smaller than each of a mean particle diameter of the second condensed phase 11 and a mean particle diameter of the third condensed phase 13. In this case, it is easy to improve the heat resistance of the cemented carbide 1.

The mean particle diameter of the third condensed phase 13 may be smaller than the mean particle diameter of the second condensed phase 11. In this case, it is easy to improve the heat resistance of the cemented carbide 1.

The mean particle diameter of the second condensed phase 11 may be larger than each of the mean particle diameter of the first condensed phase 9 and the mean particle diameter of the third condensed phase 13. In this case, it is easy to improve the heat resistance of the cemented carbide 1.

The mean particle diameter of the first condensed phase 9 is not limited to specific dimensions. This is also true for the mean particle diameter of the second condensed phase 11 and the mean particle diameter of the third condensed phase 13. The mean particle diameter of the first condensed phase 9 may be 0.5-4 μm. The mean particle diameter of the second condensed phase 11 may be 1.5-5 μm. The mean particle diameter of the third condensed phase 13 may be 1-4.5 μm.

The mean particle diameter of the first condensed phase 9 may be measured by image analysis. In this case, an equivalent circle diameter may be regarded as the mean particle diameter of the first condensed phase 9. The mean particle diameter of the first condensed phase 9 may be measured in the following procedure. Firstly, a cross section of the cemented carbide 1 is observed at 3000-5000× magnification with an SEM so as to obtain an SEM image. At least 50 pieces or more of the first condensed phase 9 in the SEM image may be identified and extracted. Thereafter, the mean particle diameter of the first condensed phase 9 may be obtained by calculating an equivalent circle diameter with the use of image analysis software ImageJ (1.52). The mean particle diameter of the second condensed phase 11 and the mean particle diameter of the third condensed phase 13 may be measured in the same procedure as in the mean particle diameter of the first condensed phase 9.

### Method for Manufacturing Cemented Carbide

A method for manufacturing a cemented carbide in a non-limiting embodiment of the present disclosure is described below by exemplifying the case of manufacturing the cemented carbide 1.

Firstly, WC powder, Co powder, TiC powder, ZrC powder, NbC powder, and TaC powder may be prepared as raw material powder.

A proportion of the Co powder may be 4-15 mass % (wt %). A proportion of the Tic powder may be 0.5-5 mass %. A proportion of the ZrC powder may be 0.2-5 mass %. A proportion of the NbC powder may be 0.1-3 mass %. A proportion of the TaC powder may be 0.1-5 mass %. The rest may be WC powder. The proportion of the ZrC powder may be set to be larger than the proportion of the NbC powder.

Mean particle diameters of the raw material powders may be suitably selected in a range of 0.1-10 μm. The mean particle diameters of the raw material powders may be values measured by micro track method.

A molded body may be obtained by mixing the prepared raw material powders, followed by molding. Examples of molding method may include press molding, cast molding, extrusion molding, and cold isostatic press molding.

The obtained molded body may be subjected to debinding treatment, followed by sintering. The sintering may be carried out in a non-oxidizing atmosphere, such as vacuum, argon atmosphere, and nitrogen atmosphere. A sintering temperature may be 1450-1600° C. Sintering time may be 0.5-3 hours.

The cemented carbide 1 may be obtained by cooling after sintering. In this case, a condition to keep for 0.25-2 hours in a temperature range of 900-1400° C. may be set to a cooling step. If this keeping (keeping temperature and keeping time) is set to the cooling step, it is easy to form the condensed phase 7 whose Nb/(Zr+Nb) in terms of atomic ratio is less than 0.38. It is also easy to form the condensed phase 7 including the first condensed phase 9, the second condensed phase 11, and the third condensed phase 13.

The above manufacturing method is one embodiment of the method for manufacturing the cemented carbide 1. Therefore, it is needless to say that the cemented carbide 1 is not limited to one which is manufactured by the above manufacturing method.

### Coated Tool

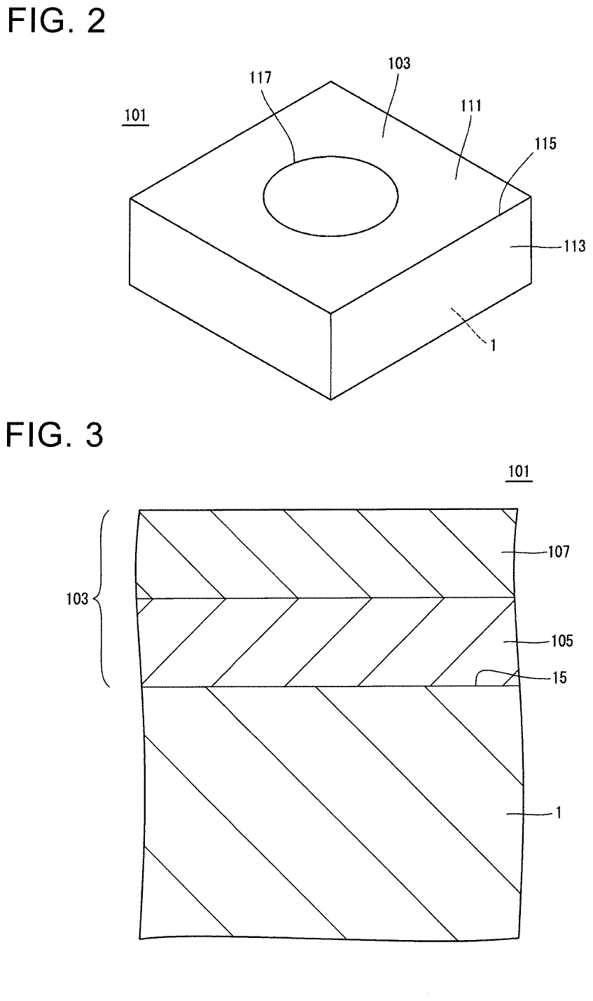

A coated tool 101 in a non-limiting embodiment of the present disclosure is described below with reference to FIGS. 2 to 4 by exemplifying the case of including the cemented carbide 1 described above.

The coated tool 101 may include the cemented carbide 1 and a coating layer 103 located on a surface 15 of the cemented carbide 1 as in the non-limiting embodiment illustrated in FIGS. 2 to 4. The coated tool 101 may include the cemented carbide 1 as a base. If the coated tool 101 includes the cemented carbide 1, wear due to heat can be avoided because of high heat resistance of the cemented carbide 1. This leads to high wear resistance of the cemented carbide 1 (base), and the coated tool 101 has high durability in combination with wear resistance owing to the coating layer 103.

The coating layer 103 may be located on the whole or a part of the surface 15 of the cemented carbide 1. That is, the coating layer 103 may be located on at least the part of the surface 15 of the cemented carbide 1.

The coating layer 103 may be deposited by chemical vapor deposition (CVD) method. In other words, the coating layer 103 may be a CVD film. Alternatively, the coating layer 103 may be a PVD film deposited by physical vapor deposition (PVD) method.

The coating layer 103 may be configured with a single layer or may be configured with a plurality of laminated layers. Examples of composition of the coating layer 103 may include TiCN (titanium carbonitride), Al₂O₃ (alumina), and TiN (titanium nitride).

The coating layer 103 may include a TiCN layer 105 and an Al₂O₃ layer 107 in sequence from a side of the cemented carbide 1 as in the non-limiting embodiment illustrated in FIG. 3. The TiCN layer 105 may be in contact with the cemented carbide 1. The Al₂O₃ layer 107 may be in contact with the TiCN layer 105.

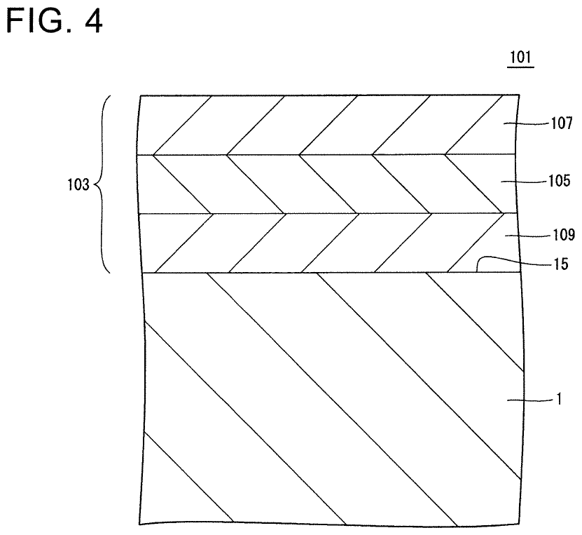

The coating layer 103 may include a TiN layer 109, the TiCN layer 105, and the Al₂O₃ layer 107 in sequence from a side of the cemented carbide 1 as in the non-limiting embodiment illustrated in FIG. 4. The TiN layer 109 may be in contact with the cemented carbide 1. The TiCN layer 105 may be in contact with the TiN layer 109. The Al₂O₃ layer 107 may be in contact with the TiCN layer 105.

The coating layer 103 is not limited to having a specific thickness. For example, a thickness of the TiCN layer 105 may be set to approximately 1-15 μm. A thickness of the Al₂O₃ layer 107 may be set to approximately 1-15 μm. A thickness of the TiN layer 109 may be set to approximately 0.1-5 μm. The thickness of the coating layer 103 may be measured by a cross sectional observation using an electron microscope. The thickness of the coating layer 103 may be an average value. For example, the thickness may be measured at 10 or more measuring points at 1 μm intervals with a width of 10 μm or more at an arbitrary position of the individual layers, and an average value thereof may be calculated.

FIG. 2 illustrates a cutting insert as a non-limiting embodiment of the coated tool 101. The coated tool 101 is not limited to the cutting insert.

The coated tool 101 may include a first surface 111 (upper surface), a second surface 113 (lateral surface) adjacent to the first surface 111, and a cutting edge 115 located on at least a part of a ridge line part of the first surface 111 and the second surface 113.

The first surface 111 may be a rake surface. The whole or a part of the first surface 111 may be the rake surface. For example, a region along the cutting edge 115 in the first surface 111 may be the rake surface.

The second surface 113 may be a flank surface. The whole or a part of the second surface 113 may be the flank surface. For example, a region along the cutting edge 115 in the second surface 113 may be the flank surface.

The cutting edge 115 may be located on a part or the whole of the ridgeline part. The cutting edge 115 is usable for machining a workpiece.

The coated tool 101 may include a through hole 117. The through hole 117 is usable for attaching a fixing screw or clamping member when holding the coated tool 101 in a holder. The through hole 117 may be formed from the first surface 111 to a surface (lower surface) located on a side opposite to the first surface 111, and the through hole 117 may also open into these surfaces. There is no problem even if the through hole 117 is configured to open into regions opposed to each other in the second surface 113.

The coated tool 101 may have a quadrangular plate shape. The shape of the coated tool 101 is not limited to the quadrangular plate shape. For example, the first surface 111 may have a triangular shape, a pentagonal shape, a hexagonal shape, or a circular shape.

The coated tool 101 is not limited to having specific dimensions. For example, a length of one side of the first surface 111 may be set to approximately 3-20 mm. A height from the first surface 111 to the surface (lower surface) located on the side opposite to the first surface 111 may be set to approximately 5-20 mm.

### Method for Manufacturing Coated Tool

A method for manufacturing a coated tool in a non-limiting embodiment of the present disclosure is described below by exemplifying the case of manufacturing the coated tool 101.

The coated tool 101 may be obtained by depositing a coating layer 103 on a surface 15 of a cemented carbide 1 by CVD method.

A TiCN layer 105 may be deposited as follows. Firstly, a mixed gas composed of 0.1-10 vol % of titanium tetrachloride (TiCl₄) gas, 10-60 vol % of nitrogen (N₂) gas, 0.1-15 vol % of methane (CH₄) gas, and the rest that is hydrogen (H₂) gas may be prepared as a reaction gas composition. The mixed gas may be introduced into a chamber to deposit the TiCN layer 105 by setting a temperature of 800-1100° C. and a pressure of 5-30 kPa.

An Al₂O₃ layer 107 may be deposited as follows. Firstly, a mixed gas composed of 0.5-5 vol % of aluminum trichloride (AlCl₃) gas, 0.5-3.5 vol % of hydrogen chloride (HCl) gas, 0.5-5 vol % of carbon dioxide (CO₂) gas, 0.5 vol % or less of hydrogen sulfide (H₂S) gas, and the rest that is hydrogen (H₂) gas may be prepared as a reaction gas composition. The mixed gas may be introduced into the chamber to deposit the Al₂O₃ layer 107 by setting a temperature of 930-1010° C. and a pressure of 5-10 kPa.

A TIN layer 109 may be deposited as follows. Firstly, a mixed gas composed of 0.1-10 vol % of titanium tetrachloride (TiCl₄) gas, 10-60 vol % of nitrogen (N₂) gas, and the rest that is hydrogen (H₂) gas may be prepared as a reaction gas composition. The mixed gas may be introduced into the chamber to deposit the TiN layer 109 by setting a temperature of 800-1010° C. and a pressure of 10-85 kPa.

The above manufacturing method is an embodiment of the method for manufacturing the coated tool 101. Therefore, it is needless to say that the coated tool 101 is not limited to one which is manufactured by the above manufacturing method.

### Cutting Tool

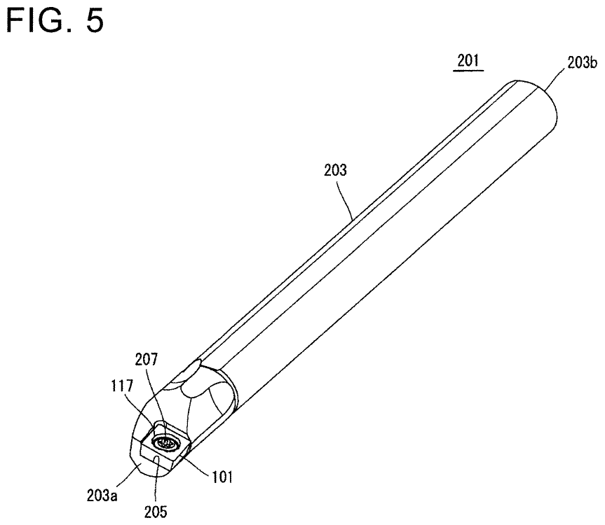

A cutting tool 201 in a non-limiting embodiment of the present disclosure is described below with reference to FIG. 5 by exemplifying the case of including the coated tool 101.

The cutting tool 201 may include a holder 203 that extends from a first end 203a toward a second end 203b and includes a pocket 205 on a side of the first end 203a, and the coating tool 101 located in the pocket 205. If the cutting tool 201 includes the coated tool 101, a stable machining becomes possible because of the high durability of the coated tool 101.

The pocket 205 may be a part to which the coated tool 101 is attached. The pocket 205 may open into an outer peripheral surface of the holder 203 and an end surface on a side of the first end 203a.

The coated tool 101 may be attached to the pocket 205 so that a cutting edge 115 can be protruded outward from the holder 203. The coated tool 101 may also be attached to the pocket 205 by a fixing screw 207. That is, the coated tool 101 may be attached to the pocket 205 by inserting the fixing screw 207 into the through hole 117 of the coated tool 101, and by inserting a front end of the fixing screw 207 into a screw hole formed in the pocket 205 so as to establish engagement between screw parts. In this case, a lower surface of the coated tool 101 may be directly contacted with the pocket 205, or alternatively, a sheet may be held between the coated tool 101 and the pocket 205.

For example, steel and cast iron are usable as a material of the holder 203. If the material of the holder 203 is steel, the holder 203 has high toughness.

The cutting tool 201 used for a so-called turning process is exemplified in the embodiment illustrated in FIG. 5. Examples of the turning process may include internal machining, external machining, and grooving process. The use of the cutting tool 201 is not limited to the turning process. For example, there is no problem even if the cutting tool 201 is used for a milling process.

Although the cemented carbide 1, the coated tool 101, and the cutting tool 201 in the non-limiting embodiments of the present disclosure have been exemplified above, it is needless to say that the present disclosure is not limited to the above embodiments, but may be applied to any embodiment without departing from the scope of the present disclosure.

For example, even though the above non-limiting embodiments have illustrated and described the case of applying the cemented carbide 1 to the coated tool 101 and the cutting tool 201, the cemented carbide 1 is applicable to other uses. Examples of other uses may include wear-resistant components such as sliding components and metal molds, digging tools, tools such as edged tools, and impact-resistant components.

Although the present disclosure is described in detail below by giving Examples, the present disclosure is not limited to the following Examples.

### EXAMPLES

### Samples Nos. 1 to 4

### Manufacturing of Cemented Carbide

Firstly, WC powder whose mean particle diameter was 3 μm, Co power whose mean particle diameter was 1.5 μm, TiC powder whose mean particle diameter was 1 μm, ZrC powder whose mean particle diameter was 1 μm, NbC powder whose mean particle diameter was 1 μm, and TaC powder whose mean particle diameter was 1 μm were prepared as raw material powder. These mean particle diameters of the raw material powders were values measured by micro-track method.

Subsequently, a molded body was obtained by mixing the raw material powders together so that a composition of a condensed phase in a sintered body could become a composition presented in Table 1, followed by press molding into a cutting tool shape (CNMG120408). The obtained molded body was subjected to debinding treatment and was kept at 1450-1600° C. for 0.5-2 hours, followed by sintering. Then, after the sintering, cooling under cooling conditions presented in Table 2 was carried out to obtain a cemented carbide composed of a sintered body including a condensed phase having a composition presented in Table 1.

An elementary analysis was made with EDS. Specifically, a cross-sectional observation was made with the EDS included in an SEM. Three arbitrary locations were measured at 5000-20000× magnification, and an average value thereof was calculated. Also, Nb/(Zr+Nb) in terms of atomic ratio was calculated from the average value.

Results of the measurements with the EDS showed that all of obtained cemented carbides included a hard phase containing W and C as a main component, and a binding phase composed of iron group metal (Co). Although Samples Nos. 3 and 4 included a condensed phase whose Nb/(Zr+Nb) value in terms of atomic ratio was different from a numeral range of first to third condensed phases, these were conveniently presented in columns of first to third condensed phases in Tables 1 and 2.

### Evaluation

A machining evaluation was made on the obtained cemented carbides. Specifically, a coated tool was manufactured by depositing a TiN layer having a thickness of 1 μm, a TiCN layer having a thickness of 10 μm, and an Al₂O₃ layer having a thickness of 5 μm in sequence from a side of the cemented carbide (base) by CVD method. Thereafter, the machining evaluation was made under the following conditions. A thickness of each of these layers is an average value.
Machining Type: Turning
Cutting Speed: 300 m/min
Feed: 0.3 mm/rev
Depth of Cut: 2 mm
Workpiece: SCM435 ϕ200 round rod
Machining State: WET

Evaluation results are shown in Table 2. The term “an amount of wear of a flank surface” in the evaluation results in Table 2 indicates an amount of wear in the flank surface at a cutting edge during a machining process.

TABLE 1

| Sample | Composition of first condensed phase (at %) | | | | | | | Composition of second condensed phase (at %) | | | |
|---|---|---|---|---|---|---|---|---|---|---|---|
| No. | C | Ti | Co | Zr | Nb | Ta | W | C | Ti | Co | Zr |
| 1 | 78.78 | 2.10 | 0.33 | 8.26 | 1.74 | 1.27 | 7.52 | 71.50 | 9.31 | 0.58 | 2.43 |
| 2 | 77.80 | 2.30 | 0.48 | 7.90 | 2.10 | 1.44 | 7.98 | 72.70 | 9.18 | 0.51 | 2.33 |
| 3 | 79.03 | 2.01 | 0.36 | 6.10 | 3.90 | 1.31 | 7.29 | 70.40 | 9.66 | 0.44 | 1.90 |
| 4 | 79.37 | 2.19 | 0.30 | 6.20 | 3.80 | 1.12 | 7.02 | 72.20 | 9.58 | 0.62 | 1.98 |

| Sample | Composition of second condensed phase (at %) | | | Composition of third condensed phase (at %) | | | | | | |
|---|---|---|---|---|---|---|---|---|---|---|
| No. | Nb | Ta | W | C | Ti | Co | Zr | Nb | Ta | W |
| 1 | 1.10 | 4.41 | 10.67 | 72.32 | 12.00 | 0.47 | 2.97 | 1.60 | 0.68 | 9.96 |
| 2 | 1.20 | 4.02 | 10.06 | 74.10 | 11.03 | 0.52 | 2.87 | 1.70 | 0.59 | 9.19 |
| 3 | 1.63 | 4.62 | 11.35 | 70.86 | 12.60 | 0.43 | 2.15 | 2.42 | 0.91 | 10.63 |
| 4 | 1.55 | 3.97 | 10.10 | 71.09 | 11.68 | 0.50 | 2.37 | 2.20 | 0.60 | 11.56 |

TABLE 2

| | Nb/(Zr + Nb) | | | | | | |
|---|---|---|---|---|---|---|---|
| | in terms of atomic ratio | | | Cooling condition | | | Evaluation result |
| | First | Second | Third | Keeping | Keeping | Cutting | Amount of wear of |
| Sample | condensed | condensed | condensed | temperature | time | time | flank surface |
| No. | phase | phase | phase | (° C.) | (hrs) | (min) | (mm) |
| 1 | 0.17 | 0.31 | 0.35 | 1200 | 1.5 | 21.1 | 0.08 |
| 2 | 0.21 | 0.34 | 0.37 | 1200 | 1.0 | 21.1 | 0.12 |
| 3 | 0.39 | 0.46 | 0.53 | — | — | 21.1 | 0.25 |
| 4 | 0.38 | 0.44 | 0.48 | — | — | 21.1 | 0.21 |

Samples Nos. 1 and 2 apparently showed improved stability compared to Samples Nos. 3 and 4.

Mean particle diameters of the first to third condensed phases in Samples Nos. 1 and 2 were measured by the above-mentioned image analysis. As a result, the mean particle diameters of the first to third condensed phases had the following relationship: the second condensed phase>the third condensed phase>the first condensed phase.

### DESCRIPTION OF THE REFERENCE NUMERAL

1 cemented carbide
3 hard phase
5 binding phase
7 condensed phase
9 first condensed phase
11 second condensed phase
13 third condensed phase
15 surface
101 coated tool
103 coating layer
105 TiCN layer
107 Al₂O₃ layer
109 TiN layer
111 first surface (upper surface)
113 second surface (lateral surface)
115 cutting edge
117 through hole
201 cutting tool
203 holder
203a first end
203b second end
205 pocket
207 fixing screw

1. A cemented carbide, comprising:
a hard phase comprising W and C;
a binding phase comprising one or more kinds of iron group metals; and
a condensed phase comprising Zr and Nb in which Nb/(Zr+Nb) in terms of atomic ratio is less than 0.38.

2. The cemented carbide according to claim 1, wherein the condensed phase comprises a first condensed phase in which Nb/(Zr+Nb) in terms of atomic ratio is 0.25 or less.

3. The cemented carbide according to claim 2, wherein the condensed phase further comprises
a second condensed phase in which Nb/(Zr+Nb) in terms of atomic ratio is larger than 0.3 and 0.34 or less, and
a third condensed phase in which Nb/(Zr+Nb) in terms of atomic ratio is larger than 0.34 and less than 0.38.

4. The cemented carbide according to claim 3, wherein a mean particle diameter of the first condensed phase is smaller than each of a mean particle diameter of the second condensed phase and a mean particle diameter of the third condensed phase.

5. The cemented carbide according to claim 3, wherein a mean particle diameter of the third condensed phase is smaller than a mean particle diameter of the second condensed phase.

6. A coated tool, comprising:
the cemented carbide according to claim 1; and
a coating layer located on a surface of the cemented carbide.

7. The coated tool according to claim 6, wherein the coating layer comprises a TiCN layer and an Al₂O₃ layer in sequence from a side of the cemented carbide.

8. The coated tool according to claim 6, wherein the coating layer comprises a TiN layer, a TiCN layer, and an Al₂O₃ layer in sequence from a side of the cemented carbide.

9. A cutting tool, comprising:
a holder that extends from a first end toward a second end and comprises a pocket on a side of the first end; and
the coated tool according to claim 6, which is located in the pocket.
